(19) United States
(12) Patent Application Publication
(10) Pub. No.: US 2023/0207385 A1
(43) Pub. Date: Jun. 29, 2023

(54) TECHNIQUES FOR CREATING BLIND ANNULAR VIAS FOR METALLIZED VIAS

(71) Applicant: CORNING INCORPORATED, CORNING, NY (US)

(72) Inventors: Patrick Scott Leslie, Tucson, AZ (US); Chukwudi Azubuike Okoro, Painted Post, NY (US)

(21) Appl. No.: 17/928,363

(22) PCT Filed: Jun. 14, 2021
(86) PCT No.: PCT/US2021/037158

§ 371 Date: Nov. 29, 2022

Related U.S. Application Data
(60) Provisional application No. 63/041,305, filed on Jun. 19, 2020.

(51) Int. Cl. H01L 21/768; B23K 26/0622; B23K 26/06; B23K 26/386; H01L 21/48; H01L 23/498

(52) U.S. Cl. CPC H01L 21/76825; B23K 26/386; B23K 26/0624; B23K 26/0648; H01L 21/486; H01L 23/49827; B23K 2101/40

(57) ABSTRACT

Systems, devices, and techniques for creating blind annular vias for metallized vias are described. For example, a vortex beam may be applied to an optically transmissive substrate, where the vortex beam may modify a portion of the substrate in an annular shape. The annular shape may extend from a surface of the substrate to a depth that is less than a thickness of the substrate, and the annular shape may have an annular width (e.g., a ring width) that is the same for various diameters of the annular shape. A blind annular via may be formed by etching the modified portion of the substrate, where the blind annular via may include a pillar comprising the same material as the surrounding substrate. In addition, a metallized annular via may be created by filling the blind annular via with a conductive material, and removing a portion of the substrate opposite the surface.

This application claims the benefits of priority under 35 U.S.C. § 371 of International Application Serial No.: PCT/US2021/037158, filed on Jun. 14, 2021, which claims the benefit of priority under 35 U.S.C. § 119 of U.S. Provisional Application Serial No. 63/041305 filed on Jun. 19, 2020, the contents of which are relied upon and incorporated herein by reference in their entirety.

### TECHNICAL FIELD

The following relates generally to optically transmissive substrates and more specifically to techniques for creating blind annular vias for metallized vias.

### BACKGROUND

Electronic devices may include various configurations of their circuitry. One such configuration may include the use of vertical interconnect accesses, which may also be referred to as vias, enabling electrical connections between different layers of an electrical circuit. In some examples, 2.5D (e.g., interposer-type) integrated circuits may include one or more vias that carry electrical signals between dice through an interposer substrate (e.g., comprising silicon or glass). In some examples, a 3D integrated circuit may include two or more stacked dice in different planes, where the dice may be mounted, for example, on top of one another. Vias may be employed to enable the respective dice to communicate with one another.

### SUMMARY

The methods, apparatus, and devices of this disclosure each have several new and innovative aspects. This summary provides some examples of these new and innovative aspects, but the disclosure may include new and innovative aspects not included in this summary.

A method is described. The method may include applying a vortex beam to a substrate that is optically transmissive, the vortex beam modifying a portion of the substrate in an annular shape that extends from a surface of the substrate to a depth of the substrate that may be less than a thickness of the substrate. In some examples, the method may include forming a blind annular via to at least the depth by etching the portion of the substrate in the annular shape, the blind annular via surrounding a pillar including a same material as the substrate, where the blind annular via has an annular width that is independent of a diameter of the annular shape.

An apparatus may include a processor, memory in electronic communication with the processor, and instructions stored in the memory. The instructions may be executable by the processor to cause the apparatus to apply a vortex beam to a substrate that is optically transmissive, the vortex beam modifying a portion of the substrate in an annular shape that extends from a surface of the substrate to a depth of the substrate that may be less than a thickness of the substrate. The instructions may be executable by the processor to cause the apparatus to form a blind annular via to at least the depth by etching the portion of the substrate in the annular shape, the blind annular via surrounding a pillar including a same material as the substrate, where the blind annular via has an annular width that is independent of a diameter of the annular shape.

Another apparatus may include means for applying a vortex beam to a substrate that is optically transmissive, the vortex beam modifying a portion of the substrate in an annular shape that extends from a surface of the substrate to a depth of the substrate that is less than a thickness of the substrate. The apparatus may include means for forming a blind annular via to at least the depth by etching the portion of the substrate in the annular shape, the blind annular via surrounding a pillar including a same material as the substrate, where the blind annular via has an annular width that is independent of a diameter of the annular shape.

Some examples of the method and apparatuses described herein may further include operations, features, means, or instructions for applying a second vortex beam to the substrate, the vortex beam modifying a second portion of the substrate in a second annular shape that extends from the surface of the substrate to a second depth of the substrate that may be less than the thickness of the substrate, where a second diameter of the second annular shape is different than the diameter of the annular shape. Some examples of the method and apparatuses described herein may further include operations, features, means, or instructions for forming a second blind annular via to at least the second depth by etching the second portion of the substrate in the second annular shape, the second blind annular via surrounding a second pillar including the same material as the substrate, where the second bind annular via may have a second annular width that is the same as the annular width and may be independent of the second diameter of the second annular shape.

In some examples of the method and apparatuses described herein, applying the vortex beam to the substrate may include forming a damage track corresponding to the portion of the substrate that extends from the surface of the substrate to the depth of the substrate, the damage track corresponding to a focal region of the vortex beam within the portion of the substrate, where the annular shape has an annular width that may be independent of the diameter of the annular shape based on applying the vortex beam.

In some examples of the method and apparatuses described herein, applying the vortex beam to the substrate may include applying a single pulse of the vortex beam to form the damage track, where the vortex beam may be formed by an illumination source.

Some examples of the method and apparatuses described herein may further include operations, features, means, or instructions for depositing an adhesion layer in contact with the blind annular via formed by etching the portion of the substrate, depositing a seed layer in contact with the adhesion layer, and filling the blind annular via with a conductive material in contact with the seed layer. Some examples of the method and apparatuses described herein may further include operations, features, means, or instructions for forming a metallized annular via by removing a portion of the conductive material, the seed layer, the adhesion layer, or any combination thereof, where the portion of the substrate modified by applying the vortex beam to the substrate does not include a second portion of the substrate at a center of the metallized annular via.

Some examples of the method and apparatuses described herein may further include operations, features, means, or instructions for polishing the metallized annular via after removing at least the portion of the conductive material, where the polished metallized annular via may be helium hermetic having a leak rate of less than or equal to 1 × 10⁻⁵ standard atmosphere-cubic centimeters per second (atm-cc/s).

In some examples of the method and apparatuses described herein, a ring thickness of the metallized annular via may be less than 12 micrometers (µm), and the substrate including the metallized annular via may exclude cracks after an annealing process having temperatures up to 420° C. (°C) may be applied to the substrate.

In some examples of the method and apparatuses described herein, forming the blind annular via by etching may include etching, while the pillar is in contact with the substrate, the portion of the substrate radially inward and radially outward with respect to the annular shape.

Some examples of the method and apparatuses described herein may further include operations, features, means, or instructions for configuring an order of the vortex beam, where applying the vortex beam to the substrate may be based on configuring the order of the vortex beam, and the diameter of the annular shape may be based on the order of the vortex beam.

Some examples of the method and apparatuses described herein may further include operations, features, means, or instructions for configuring a focal region of the vortex beam, where the depth of the portion of the substrate may be based on the focal region of the vortex beam.

Some examples of the method and apparatuses described herein may further include operations, features, means, or instructions for configuring the vortex beam at a wavelength that is transparent to the substrate, where a region of the vortex beam that is different than a focal region of the vortex beam may pass through the substrate based on the wavelength.

An apparatus may include a substrate that is optically transmissive and includes one or more annular vias formed by a vortex beam in an annular shape that may be etched, the annular shape having an annular width that may be a same size for one or more diameters of the annular shape, where the one or more annular vias extend from a surface of the substrate to a depth of the substrate and each of the one or more annular vias surround a pillar including a same material as the substrate.

In some examples, the one or more annular vias include a first annular via having a first diameter and a second annular via having a second diameter greater than the first diameter, the first annular via and the second annular via having the annular width. In some examples, the annular width may be less than or equal to 12 µm. In some cases, each annular via of the one or more annular vias may include a metallized annular via including conducting material surrounding the pillar, where the substrate may exclude cracks after temperatures of up to 420° C. are applied to the substrate. In some examples, the substrate includes a glass material.

In some examples, the metallized annular via may be helium hermetic having a helium leak rate less than or equal to 1 × 10⁻⁵ atm-cc/s, and where a center portion of the pillar includes substrate material that may not be modified by the vortex beam. In some examples, the annular shape includes a non-scalloped profile based on the vortex beam.

A method is described. The method may include modifying, using a first vortex beam, a first portion of an optically transmissive substrate to form a first damage track having a first annular shape that extends from a surface of the optically transmissive substrate to a first depth of the optically transmissive substrate that may be less than a thickness of the optically transmissive substrate, the first annular shape having a first annular width. In some cases, the method may include modifying, using a second vortex beam, a second portion of the optically transmissive substrate to form a second damage track having a second annular shape that extends from the surface of the optically transmissive substrate to a second depth of the optically transmissive substrate, the second annular shape having the first annular width, where a second diameter of the second annular shape may be different than a diameter of the first annular shape. The method may further include forming a first blind annular via by etching the first damage track in the first annular shape and forming a second blind annular via by etching the second damage track in the second annular shape.

An apparatus may include a processor, memory in electronic communication with the processor, and instructions stored in the memory. The instructions may be executable by the processor to cause the apparatus to modify, using a first vortex beam, a first portion of an optically transmissive substrate to form a first damage track having a first annular shape that extends from a surface of the optically transmissive substrate to a first depth of the optically transmissive substrate that may be less than a thickness of the optically transmissive substrate, the first annular shape having a first annular width. In some cases, the instructions may be executable by the processor to cause the apparatus to modify, using a second vortex beam, a second portion of the optically transmissive substrate to form a second damage track having a second annular shape that extends from the surface of the optically transmissive substrate to a second depth of the optically transmissive substrate, the second annular shape having the first annular width, where a second diameter of the second annular shape may be different than a diameter of the first annular shape. The instructions may be further executable by the processor to cause the apparatus to form a first blind annular via by etching the first damage track in the first annular shape and form a second blind annular via by etching the second damage track in the second annular shape.

Another apparatus may include means for modifying, using a first vortex beam, a first portion of an optically transmissive substrate to form a first damage track having a first annular shape that extends from a surface of the optically transmissive substrate to a first depth of the optically transmissive substrate that may be less than a thickness of the optically transmissive substrate, the first annular shape having a first annular width. In some cases, the apparatus may include means for modifying, using a second vortex beam, a second portion of the optically transmissive substrate to form a second damage track having a second annular shape that extends from the surface of the optically transmissive substrate to a second depth of the optically transmissive substrate, the second annular shape having the first annular width, where a second diameter of the second annular shape may be different than a diameter of the first annular shape. The apparatus may further include means for forming a first blind annular via by etching the first damage track in the first annular shape and means for forming a second blind annular via by etching the second damage track in the second annular shape.

Some examples of the method and apparatuses described herein may further include operations, features, means, or instructions for forming, from at least one of the first blind annular via or the second blind annular via, a metallized blind annular via by filling at least one of the first blind annular via or the second blind annular via with a conductive material. Some examples of the method and apparatuses described herein may further include operations, features, means, or instructions for forming at least one metallized annular through-substrate via by modifying a third portion of the optically transmissive substrate that may be opposite the surface of the optically transmissive substrate. Some examples of the method and apparatuses described herein may further include operations, features, means, or instructions for polishing one or more surfaces of the at least one metallized annular through-substrate via, the polished metallized annular through-substrate via being helium hermetic and having a leak rate of less than or equal to 1 × 10⁻⁵ atm-cc/s. In some examples of the method and apparatuses described herein, a ring thickness of the at least one metallized annular through-substrate via may be less than 12 µm, and the optically transmissive substrate excludes cracks after the optically transmissive substrate including the at least one metallized annular through-substrate via undergoes a heating process having temperatures up to 420° C.

Some examples of the method and apparatuses described herein may further include operations, features, means, or instructions for modifying an order of the first vortex beam from a first order to a second order different than the first order, where the second diameter of the second annular shape corresponds to the second order of the second vortex beam.

In some examples of the method and apparatuses described herein, the first blind annular via surrounds a first pillar including the optically transmissive substrate, the first pillar having a third diameter, and where the second blind annular via surrounds a second pillar including the optically transmissive substrate, the second pillar having a fourth diameter different than the third diameter of the first pillar.

### BRIEF DESCRIPTION OF THE DRAWINGS

FIGS. 1A and 1B illustrate examples of systems that support techniques for creating blind annular vias for metallized vias in accordance with examples as disclosed herein.

FIGS. 2A, 2B, and 2C illustrate examples of an apparatus including a blind annular via that supports techniques for creating blind annular vias for metallized vias in accordance with examples as disclosed herein.

FIG. 3 illustrates an example of etching techniques that support techniques for creating blind annular vias for metallized vias in accordance with examples as disclosed herein.

FIG. 4 illustrates an example of an apparatus including multiple annular vias that supports techniques for creating blind annular vias for metallized vias in accordance with examples as disclosed herein.

FIGS. 5A, 5B, 5C, 5D, 5E, and 5F illustrate examples of a method for metallizing a blind annular via that supports techniques for creating blind annular vias for metallized vias in accordance with examples as disclosed herein.

FIGS. 6 and 7 show flowcharts illustrating a method or methods that support techniques for creating blind annular vias for metallized vias in accordance with examples as disclosed herein.

### DETAILED DESCRIPTION

The use of interposer substrates and stacked dice may be beneficial for circuit design, particularly as the need to save space increases for various devices (e.g., as the size of various devices decreases). As such, the performance of vias in such devices may be important for the efficiency and functionality of such circuits. The formation of vias in a substrate (e.g., glass), however, may have various structural and design challenges, such as increased stress placed on the substrate at elevated temperatures, potentially resulting in various defects in the substrate including, for example, cracks, voiding, or sidewall delamination, among others.

Integrated circuits may have various design configurations based on a functionality of an electronic device, or a form factor of an electronic device, or both. For example, miniaturization and improved electrical performance in devices may rely on the use 3D and 2.5D chip stacking architectures. These technologies, among other examples, may use vertical interconnect access, which may also be referred to as a via or VIA, where one or more vertical interconnects may be formed by creating holes in a substrate and adding a conductive path after creating the holes, leading to interconnects that provide enhanced electrical performance and enable signaling between two or more dice. Examples of vertical interconnects may include through-silicon vias (TSVs) (e.g., a conductive path through a silicon substrate) and through-glass vias (TGVs) (e.g., a conductive path through a glass or substrate), among others. In some examples, 2.5D chip stacking architectures may be relatively more cost effective, may have fewer integration challenges, and may avoid some design challenges compared to 3D chip stacking architectures. The 2.5D chip stacking architectures may include the use of a non-active substrate (e.g., having no integrated front-end devices) with one or more vias, which may be referred to as interposer substrates. Interposer substrates may be made of silicon, glass, or other materials.

In some cases, glass substrates and interposers with TGVs may enable advantages of glass substrates (e.g., as compared to silicon) including lower cost, a tunable coefficient of thermal expansion (CTE), and increased high-frequency performance, among others. The formation of TGVs, however, may present some thermo-mechanical challenges, for example, based on a CTE mismatch between a matrix of the glass (e.g., 0.6 ppm/°C for fused silica) and a metal or a conductive fill (e.g., 16.7 ppm/°C for copper). In such cases, at relatively elevated temperatures, the difference in CTE between the materials may lead to an increased stress in the substrate, resulting in different failure modes, such as cracks, TGV voiding, or sidewall delamination, among others. As such, both through hole and blind hole geometries (e.g., geometries including hourglass, cylindrical, conical, etc.) and metallization techniques (e.g., conformal, fully filled, pinched, etc.) may result in a stress profile through the glass substrate. This stress profile may lead to problems during metallization and other fabrication steps, resulting in cracking of the substrate, for example, when heated to relatively high temperatures.

To address these issues using other techniques different than the present disclosure, additional time-consuming steps or processes (e.g., in addition to the processes for creating the vias) may be used in an effort to avoid or minimize defects. Such processes may, however, increase the time and the cost of manufacturing. As a result, to leverage the improved performance and functionality provided by glass substrates, it may be beneficial to utilize techniques for quickly and efficiently creating vias that also reduce or eliminate these issues.

As described herein, techniques may be used to create blind annular vias for hermetic, crack-free metallized vias in a substrate. For example, one or more vias having an annular geometry may be formed in an optically transmissive (e.g., transparent) substrate, such as glass. The annular vias may include an annular via (e.g., a ring shaped via) with a center pillar that may be a same height or may be shorter than a height of a surrounding substrate material. The annular via created using the described techniques may be less than 12 micrometers (µm) and may be metallized to form a conductive electrical path, which may be helium hermetic (e.g., having a helium (He) leak rate less than or equal to 1 × 10⁻⁵ standard atmosphere-cubic centimeters per second (atm-cc/s)). Although the present disclosure describes a vias that are helium hermetic, it is not limited to this example, and other examples are contemplated. The metallized annular vias may also prevent the formation of thermo-mechanically driven cracks, such as when the substrate is subjected to high temperatures (e.g., up to 420° C.), for example, during annealing processes, among other benefits. In particular, the annular vias described herein may provide a geometry that may be beneficial for metallized TGVs, or conical shaped TGVs, among other examples. The geometry of the annular vias may reduce a stress profile of metallized vias by reducing the stress in the substrate due to the inclusion of a same substrate material in the middle of the metallized via (e.g., a pillar of the substrate within an annular via) as compared to air or other materials (e.g., metal oxides created through sol-gel processes). As such, metallized vias may be created that are resistant to cracks based on the reduced stress in the substrate. Additionally, the described techniques may provide for metallized blind vias or through vias that may be fully filled, or conformally filled, or both (e.g., pinched).

The annular vias described herein may be formed using a truncated vortex beam that may modify (e.g., damage) the substrate, and the modified substrate may then be etched to create the annular vias. For instance, due to a radial geometry and non-diffractive nature of vortex beams, one or more annular vias (e.g., created as a damage track in a substrate) may be quickly and efficiently formed based on non-linear absorption of an ultrafast laser pulse. In such cases, one laser pulse per damage track (e.g., corresponding to an annular via) may enable translation of a substrate (e.g., along various axes) to be used for patterning the substrate, as opposed to other techniques that may need translation of the substrate for both generation of the via and patterning.

Aspects of the present disclosure may be used to realize one or more advantages. For instance, as described above, when using a single laser pulse for creating the annular structure, a radius of the vortex beam may allow for a crack ring to form without any translation of the beam or substrate for that crack ring, thereby saving processing time when creating a given via as well as for creating multiple vias. Likewise, the properties of the vortex beam that enable the non-linear absorption within a substrate may enable ultrafast processing for efficient fabrication of vias in the substrate. Aspects of the present disclosure may further provide for crack ring etch specificity, where a crack ring (or a damage ring), for example, created by the vortex beam, may have preferential etching as compared to the undamaged substrate material. An etchant may penetrate the cylindrical damage track down into the substrate based on the preferential etch. In such cases, the substrate in the center of the crack ring may not be affected by the vortex beam, leaving the substrate materials to form a pillar structure of the annular via.

In addition, the annular structure may provide various advantages in forming conductive paths. Specifically, for various diameters of the annular structure, a relatively narrow trench of a same width may be created, which may improve downstream processes related to the annular vias. In addition, the same ring or trench width for various via diameters may replace holes having different diameter and having removed material in a ratio to their size, thereby providing increased flexibility in the configuration of the substrate and associated devices. The described techniques for creating blind annular vias may also allow for metallization of glass vias by leveraging metallization processes and tools for the making of TSVs. That is, the described techniques may enable the adoption of metallized TGVs (e.g., because TGV metallization may use a same supply chain). Accordingly, the use of a vortex beam to make blind vias may lead to reduced cost for TGV metallization (e.g., using proven supply chain platforms).

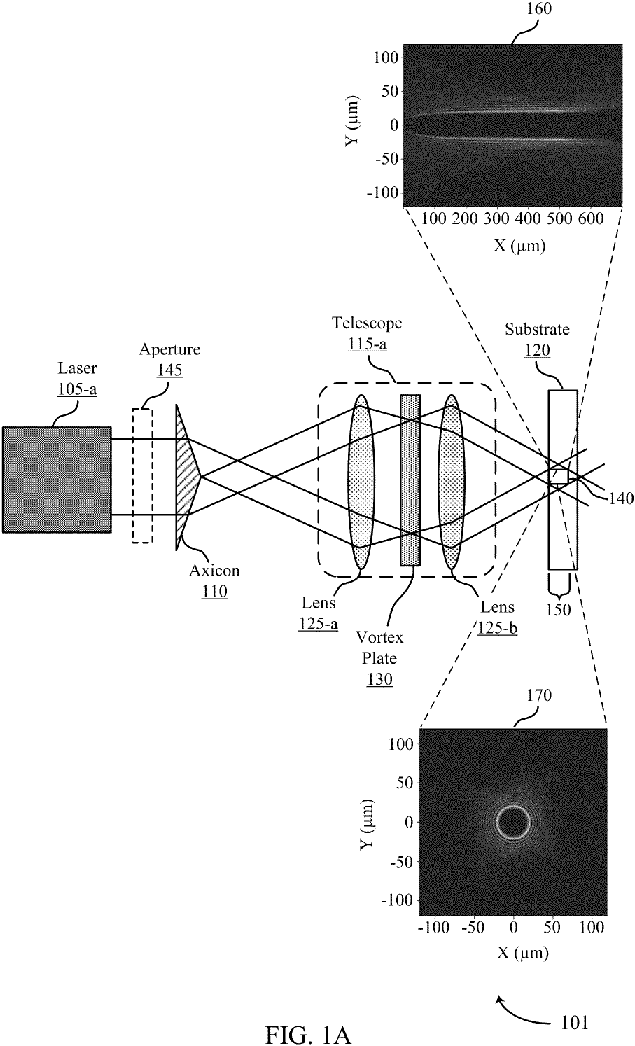

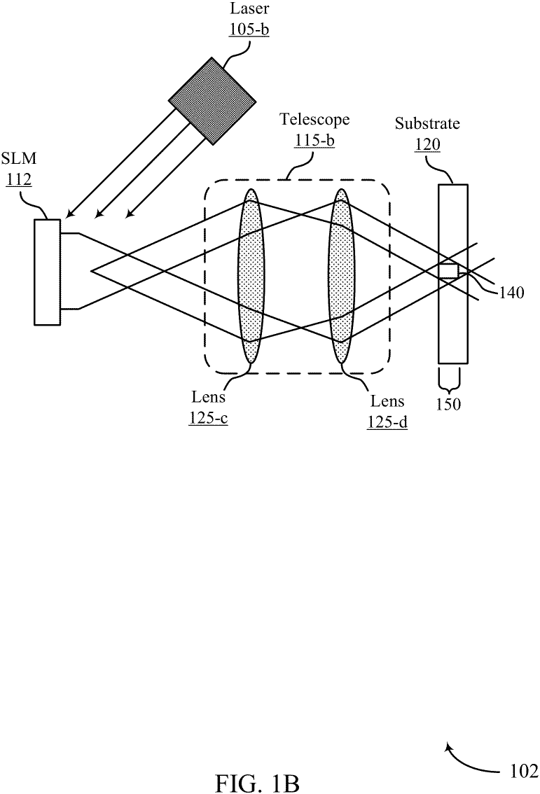

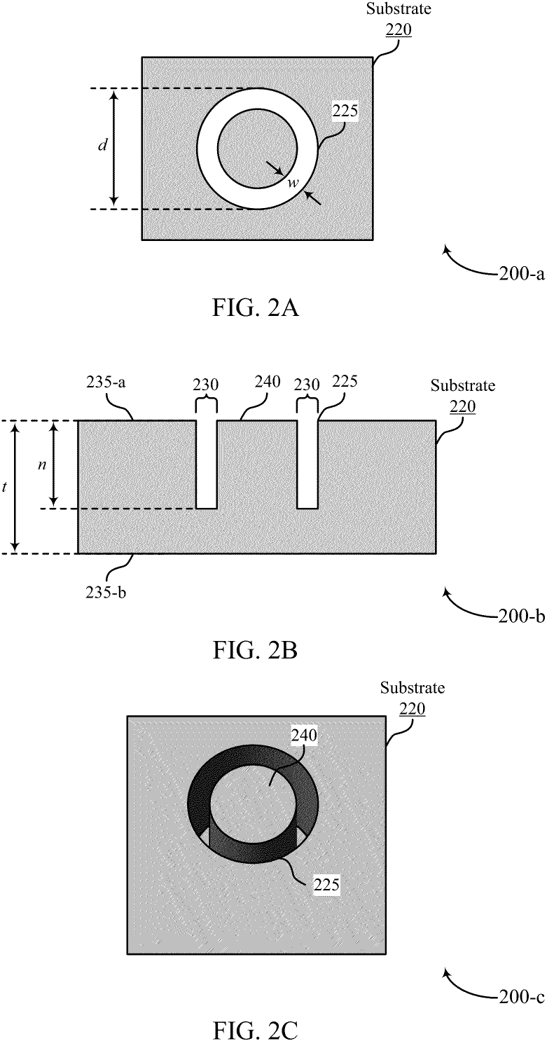

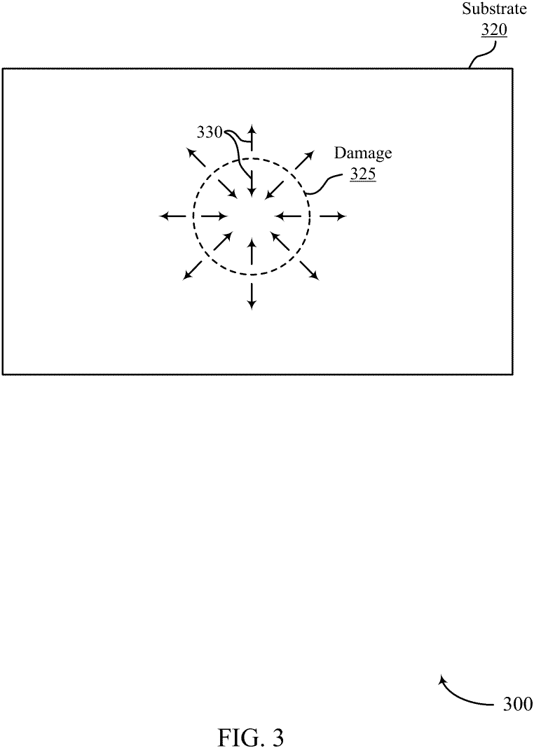

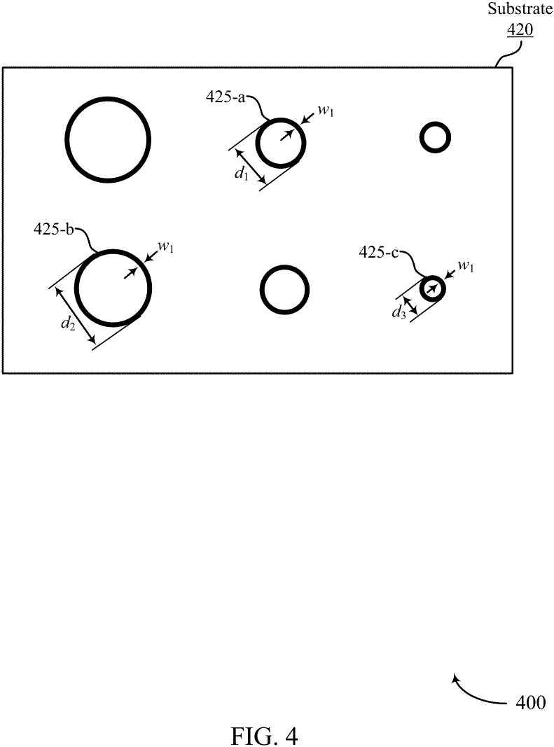

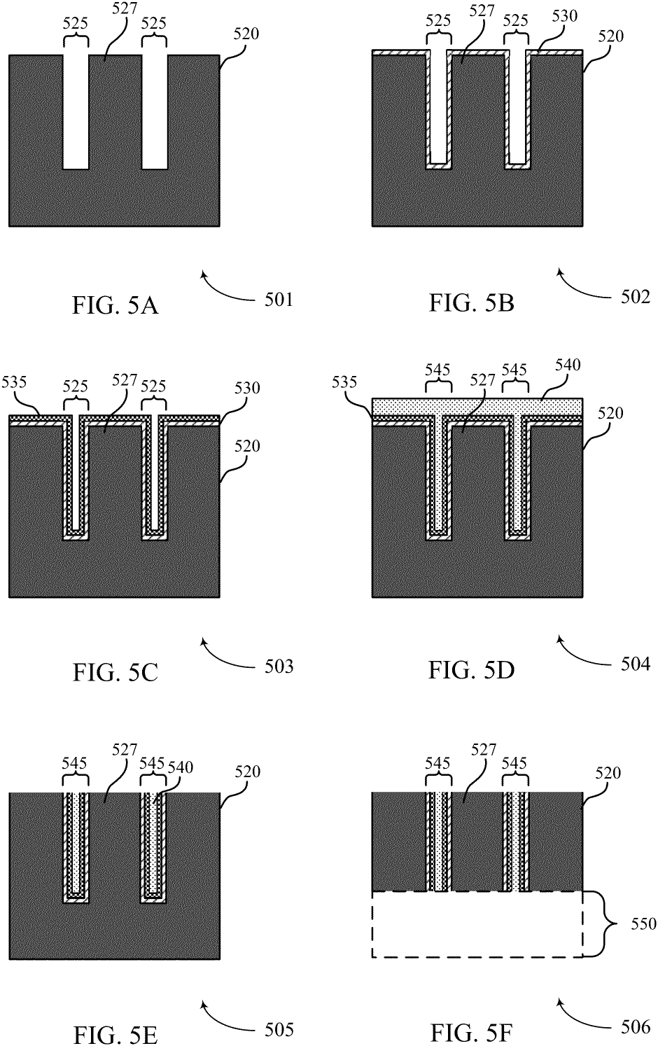

Features of the disclosure are initially described in the context of a system for creating annular vias in a transparent substrate, as described with reference to FIG. 1. Features of the disclosure are further described in the context of annular vias and etching processes with respect to FIGS. 2A-2C, and FIG. 3. Annular vias having a same ring width, the metallization of blind annular vias, and flowcharts are further described with reference to FIG. 4, FIGS. 5A-5F, and FIGS. 6-7.

FIGS. 1A and 1B illustrate examples of a system 101 and a system 102 that support techniques for creating blind annular vias for metallized vias in accordance with examples as disclosed herein. The systems 101 and 102 may include an apparatus that is used for the creation of one or more annular vias in an optically transmissive substrate. For instance, the components of the systems 101 and 102 may be used for creating a vortex beam that may be used to modify one or more portions of a substrate in an annular shape, and the modified portion may then be etched to form an annular via. As shown in FIG. 1A, the system 101 may include a laser 105-a, an axicon 110, a telescope 115-a, and a substrate 120 (e.g., an optically transmissive substrate), among other components. In some examples, the telescope 115-a may include one or more lenses 125 (e.g., lens 125-a and lens 125-b) and a vortex plate 130.

As described herein, an annular blind via may be formed in a transparent substrate, such as substrate 120. The creation of the annular structure (e.g., the annular blind via) may be accomplished using truncated vortex beam damage techniques, which may be followed by etching or other techniques to create an annular blind hole (e.g., the annular via). The vortex beam created using the systems 101 and 102 may provide advantages over other laser damage methods. In particular, an advantage of damage techniques using a vortex beam may include a geometry of the vortex beam that creates a damage track 140 in the substrate 120, where the damage track 140 may be achieved in a radial manner and from a single pulse of the laser 105-a. The ring shaped damage from the vortex beam may accordingly enable an etched geometry of a blind annular structure.

The vortex beam may be generated using a combination of one or more of the components of system 100. For example, the laser 105-a may be an example of an ultra-fast laser or other type of illuminative source or radiative source. The laser 105 may be configured to operate at a wavelength that is transparent to the substrate 120 (e.g., comprising fused silica, fused quartz, or other types of glass, among other examples) for modifying the substrate 120 based on the laser damage to the substrate 120. As such, unfocused laser light may pass through the substrate 120 without being absorbed. However, when the light is focused (e.g., reaching a relatively high intensity), nonlinear absorption may occur in a focal region 150 of the generated beam. In some examples, the laser 105-a may be configured to operate at a wavelength in the near-infrared spectrum. For instance, the laser 105-a may be configured to operate at wavelengths of 1030 nanometers (nm), and the laser 105-a may further support a tunable pulse width, for example, from about 300 femtoseconds to 10 picoseconds and utilize pulse energies up to 2 millijoule (mJ) per pulse. The laser 105-a may be configured to operate using different parameters for creating a vortex beam, including various wavelengths, pulse widths, or energies, and the examples provided are for illustrative purposes only.

The beam from the laser 105-a may pass through various optics within the system 100, where the optics may be used to generate the vortex beam that is applied to the substrate 120. For instance, the optics of the system 101 may include the axicon 110 that may provide a ring-shaped distribution of the beam generated by the laser 105-a. After leaving the axicon 110, the beam may enter the telescope 115-a. In some examples, the telescope 115-a may be an example of a telescopic system configured for spatial filtering, which may include the vortex plate 130 (e.g., a diffractive vortex plate optic). In some aspects, the telescope 115-a may be an example of a 4f system (e.g., a system that includes multiple optical components that are each separated by a focal length). In such cases, the telescope 115-a may include multiple lenses 125 (e.g., lens 125-a and lens 125-b) and the vortex plate 130 that are each be separated by a same focal length.

In some examples, the vortex plate 130 may introduce an angle, such as a skew angle, which may radially expand the beam (e.g., from a long narrow cylinder or Bessel beam) to a long hollow cylinder. For instance, a focal region of a Bessel beam may resemble a relatively long, narrow cylinder with a diameter of about 1 µm. In contrast, a focal region 150 of the vortex beam may be representative of a hollow cylinder having a larger diameter compared to the Bessel beam, as illustrated by cross-sectional view 160. Further, when looking in a propagation direction of the vortex beam, as illustrated by view 170, the vortex beam may provide a radial distribution of energy, where the center of the vortex beam may include a zero of the optical beam (e.g., an annular shape). When the vortex beam is focused in glass (e.g., the substrate 120), the beam may modify the substrate (e.g., damage the substrate) in the shape of a ring crack within the focal region 150, which may propagate through at least a portion of the substrate 120.

In some examples, to expand the vortex beam to different radii, vortex plates 130 of different orders may be added into a ring space (e.g., within the telescope 115-a) of the optical system. For instance, a relatively higher vortex plate order may provide for a larger radius of the vortex beam within the focal region 150 compared to a lower vortex plate order. In some cases, the order of the vortex plate 130 may increase from a zero order (e.g., m = 0), which may provide a Bessel beam, to higher orders, such as m = 29 (with m being the order of the vortex beam) that may have a diameter (and a corresponding damage ring) of about 30 µm. In other examples, an order of m = 93 may be used to provide a diameter (and a corresponding damage ring) of about 80 µm (e.g., using a laser 105-a configured to operate at 2 mJ). However, other orders and diameters are possible, and the examples provided are for illustrative purposes and should not be considered limiting. The order of the vortex beam may accordingly modify the annular diameter of the blind via and the size of the central pillar created in the substrate 120. The beam may be exposed to the substrate 120 in a single (e.g., ultrafast) laser pulse, in some cases, creating a damage ring corresponding to the order of the vortex plate 130 used.

In some examples, to create the damage track in the substrate 120 for the annular blind structure up to some depth (which may be less than a thickness of the substrate 120 in some examples), a physical or dynamic aperture 145 may be applied to the beam (e.g., a Gaussian beam). Additionally or alternatively, the non-diffracting beam may be focused in a portion (e.g., a subset) of the substrate 120. That is, the depth of the focal region 150 within the substrate may be modified by either adjusting the aperture 145 or by adjusting the position or location of the focal region 150 within the substrate 120. Such modification may therefore enable the creation of a damage track 140 up to some configurable depth in the substrate 120, for example, without damaging a full thickness of the substrate 120. Put another way, by adjusting the depth of the focal region 150 within the substrate 120, a blind annular via may be created that leaves a center pillar structure intact and attached to the substrate 120.

In other examples, the vortex beam may be generated using other techniques and components, such as a spatial light modulator (SLM). For example, as illustrated by FIG. 1B, the system 102 may include a laser 105-b, an SLM 112, a telescope 115-b, and the substrate 120 (e.g., an optically transmissive substrate), among other components. In some examples, the telescope 115-b may include one or more lenses 125 (e.g., lens 125-c and lens 125-d).

In some aspects, the laser 105-b may generate one or more beams (e.g., a Gaussian beam) incident on the SLM 112. The SLM 112 may be configured to modify one or both of an intensity or phase of light (e.g., from the laser 105-b), which may enable the creation of a vortex beam. For example, the SLM 112 may be configured with one or more phase masks that enable phase modification of the beam from the laser 105-b. More specifically, the SLM may be configured with an axicon phase modification or a vortex phase modification, or both, to produce a beam having a particular phase. In such cases, an axicon phase of the beam may create a Bessel beam, where the applied axicon phase and the telescope 115-b (e.g., a 4f system) may likewise result in a Bessel beam applied to the substrate 120. Further, the addition of a vortex phase modification to the axicon phase modification on the SLM may result in a vortex beam. In some cases, the vortex phase mask may be modified to add a relatively higher or lower order to the vortex beam, which may modify the vortex beam to different radii. For example, the order (e.g., m) of the vortex beam may be configured from m = 1 to any order greater than 1. In some aspects, the order of the vortex beam may be m = 100. As a result, and as illustrated in the system 102, when the Gaussian beam from the laser 105-b interacts with the SLM 112 (e.g., interacting with a screen of the SLM 112 and reflecting off one or more phase masks configured for SLM 112), the SLM 112 may create a beam that is desired (e.g., a vortex beam) for forming one or more annular vias in the substrate 120. The beam may be resized and refocused onto the substrate 120 to create a damage track 140 in the substrate 120. That is, the vortex beam created by the laser 105-b, the SLM 112, and the telescope 115-b may be used to create the damage track 140 within the focal region 150 in the substrate 120 for the annular blind structure up to some depth.

The modified substrate (e.g., damage) created by the vortex beam may include various features that give rise to the blind annular structure of the vias formed in the substrate 120. As an example, the laser damage structure, having some configured radius, may be achieved without additional translation of a stage, the substrate 120, or the vortex beam for the laser damage structure. In contrast, the use of a Bessel beam may require multiple translation to create a single structure. Further, with a single pulse from the laser 105-a or laser 105-b, the vortex beam may create damage tracks 140 with diameters ranging from the operating wavelength of the laser 105 (e.g., the laser 105-a or laser 105-b) to the limits of a pulse energy of the laser 105. If a specific annular structure radius is desired, a corresponding vortex plate may be inserted into the system 101 (e.g., in the telescope 115-a) to process the substrate 120. For instance, when creating an annular blind via with a diameter of about 30 µm, an m = 30 vortex plate may be used (e.g., for 1030 nm light from the laser 105-a). Similarly, the SLM 112 of the system 102 may be configured with different vortex phase masks that modify the order of the vortex beam.

Another aspect of the vortex beam created by the systems 101 and 102 may include an absence of damage to the substrate 120 in the center of the vortex beam. That is, the ring damage from the vortex beam may not affect the center pillar of the annular structure of the via (e.g., there may be no damage to the center of the center pillar of the annular structure of the via). As such, the damage track 140 may enable a preferential etch of the hollow cylindrical damage, whereas the center pillar and surrounding portions may be etched as a function of the material (e.g., which may be slower than the modified portion of the substrate 120 that includes the laser damage (e.g., ring crack) region). Such preferential etch may allow for the creation of the pillar inside the annular structure without additional masking or other processes.

In addition, the focus of the depth of the vortex beam may be dynamically configured and modified. Here, the vortex beam may be non-diffracting and may damage the substrate 120 by non-linear absorption. Accordingly, the vortex beam (e.g., a truncated beam) may damage the substrate 120 with precision (e.g., on the order of microns) in all axes (e.g., x, y, and z axes). This may enable the beam to damage part of the bulk of the substrate 120 so that the ultrafast damage may be achieved. In this case, the blind damage may refer to creating damage on one side of the surface of the glass, extending through a portion of the substrate 120 (e.g., less than the thickness of the substrate 120) based on a configuration of the focal region 150. Such damage may not connect to the opposite surface of the same substrate 120. With the damage being contained to a portion of the substrate 120 extending from one surface, a through via may not be formed in the substrate 120 (e.g., causing the center pillar to drop out after etching), maintaining the center pillar structure that may be used in downstream processing steps, including metallization of the annular via.

Upon removing the substrate material corresponding to the damage track 140, for example, by etching among other techniques, annular vias (e.g., annular holes) may be created. As described in further detail below, the annular vias may have a diameter of less than 12 µm, and may additionally or alternatively have a ring thickness of less than 12 µm, which may enable crack-free vias, for example, after subjection to high temperatures (e.g., up to 420° C.). In addition, the ability to make annular vias having sizes less than 12 µm, irrespective of the via diameter, may allow for multiple vias on a same substrate 120, for example, having different diameters, but consistent ring widths, thereby enhancing interposer design and flexibility. Moreover, the creation of the blind annular vias using the vortex beam may enable metallization of the vias while leaving the core center pillar (e.g., comprising the same material of the substrate 120) intact, which may provide for the reduction in stresses within the substrate 120, thereby minimizing crack formation, and thus, increasing reliability, among other benefits.

The described techniques may enable the creation of helium hermetic vias, and the use of the vortex beam to form blind annular hole, with an intact core, may maintain various advantages of a metallized conformal pinch via (CPV) that includes He hermicity and crack-free substrate after annealing to 420° C. Further, the described techniques may eliminate one or more drawbacks of CPVs including the presence of via pockets that impact via reliability (e.g., leading to via corrosion and contamination). In some examples, besides laser damage using the vortex beam and etching, other techniques to create an annular via may including masking and etching. In such cases, a surface of the substrate may be covered with a material that is not as susceptible to an etchant, leaving an open annular surface for the etchant to dissolve the substrate and create an annular hole. However, such techniques may require many process steps to create and apply the mask. In addition, masking and etching may have a slower dissolution rate compared to the preferential etch made by ultrafast laser damage from the vortex beam created using the system 100.

In other examples different from the techniques described in the present disclosure, a structure may be formed using multiple instances of truncated Bessel beams (e.g., leading to a scalloped structure as opposed to a ring structure) followed by etching, Gaussian ablation, or vortex ablation (e.g., perfect vortex ablation or diffracting vortex beam ablation). However, these methods may also be more time consuming than using the truncated vortex beam described herein, causing the via fabrication processes to be extended and inefficient. Moreover, in each of these other different methods (e.g., as compared to the use of the vortex beam described herein), multiple translations of the substrate or the beam (or both) in at least one of the xyz-axes may be needed, and may result in a scalloped structure (e.g., after etching). Such translation may further increase processing time. In addition, the use of the vortex beam may create annular vias having substantially smooth edges and a uniform annular shape, whereas other techniques may create scalloped, uneven, or inconsistent damage tracks.

FIGS. 2A, 2B, and 2C illustrate examples of an apparatus 200 including a blind annular via that supports techniques for creating blind annular vias for metallized vias in accordance with examples as disclosed herein. The apparatus 200 may include a substrate 220 that may be an example of the substrate 120 described with reference to FIG. 1. For instance, the substrate 120 may be an optically transmissive substrate (e.g., a glass material) that includes an annular blind via 225. The annular blind via 225 may have been formed through the application of a vortex beam (e.g., creating a damage track) followed by etching of the substrate 220 in the damage track.

FIG. 2A illustrates a top view of the apparatus 200-a including an annular blind via 225 (e.g., an annular blind hole) formed in the substrate 220. As illustrated, the annular shape of the annular blind via 225 may have a diameter, d, that may be based on an order of a vortex beam applied to the substrate 220. Further, the annular shape of the annular blind via 225 may have an annular width, w, that is independent of the diameter, d. That is, for one or more different diameters of the annular blind via 225 (e.g., inside diameters or outside diameters or both), the annular width, w, may be relatively constant. In some examples, the annular width may be less than or equal to 12 µm, which may reduce the occurrence of cracks or other defects in or around the annular blind via 225, such as when heat is applied to the substrate 220. Such properties of the annular blind via 225 may be based on the use of the vortex beam used to create a damage track in the substrate 220 (e.g., modify the substrate 220), and may provide for various advantages in substrate design, flexibility, and performance.

FIG. 2B illustrates a cross-sectional view of the apparatus 200-b including the annular blind via 225. As illustrated, a vortex beam may modify a portion 230 of the substrate 220 (which may then be etched), where the portion may extend from a surface 235 of the substrate 220 to some depth, n. The depth, n, may be less than a full thickness, t, of the substrate. As such, a blind annular structure may be created in the substrate 220 without damaging the substrate through the full thickness, thereby maintaining a pillar 240 within the annular shape. As described herein, the depth of the modified portion 230 may be configurable based on a focal region of the vortex beam. The vortex beam may be a non-diffracting beam damaging the portion 230 of the substrate 220 in a single shot and without damaging through to an opposite surface 235-b. The damage may be achieved through non-linear optical absorption, where any unfocused light from the vortex beam may pass through the bulk of substrate 220.

FIG. 2C illustrates a three-dimensional view of the apparatus 200-c that includes the annular blind via 225. As shown, the annular structure of the annular blind via 225 (e.g., following etching) maintains the center pillar 240 that comprises the same material as the substrate 220. Such a configuration that maintains the pillar 240 may improve a stress profile of the substrate (e.g., as compared to other via structures that include materials different than the substrate material). For example, there may be a relationship between a likelihood for the formation of cracks in a glass substrate as a function of a crack length. Based on such a relationship, cored vias (e.g., those including some core material) may result in a lowest value of energy release rate, indicating that, having a substrate core (e.g., pillar 240) may lead to a minimized likelihood for the formation cracks. In addition to enabling a conductive ring thickness of less than 12 µm for different outer via diameters (such as d illustrated in FIG. 2A), the vortex beam based techniques described herein may further improve metallized TGV reliability when the substrate core (e.g., pillar 240) remains intact. Specifically, the pillar 240 may have the same material properties as the substrate 220, which may limit the induced stresses in the substrate 220, thereby reducing the likelihood for the formation of cracks. Such properties may accordingly result in improved reliability in TGVs. Moreover, when the annular blind via 225 is metallized in downstream processes, as described in further detail herein, the metallized annular via may be helium hermetic having a leak rate less than or equal to 1 × 10⁻⁵ atm-cc/s, thereby minimizing or eliminating associated with corrosion or contamination. In addition, based on the use of the vortex beam to create an initial damage track, the annular blind via 225 may have a non-scalloped profile.

FIG. 3 illustrates an example of etching techniques 300 that support techniques for creating blind annular vias for metallized vias in accordance with examples as disclosed herein. The etching techniques 300 may be applied to a substrate 320 that includes a damage ring 325 (or a crack ring) that was created by applying a vortex beam to the substrate 320, such as described with reference to FIGS. 1 and 2. The substrate 320 may be an example of the substrates 120 and 220 described with reference to FIGS. 1, 2A, 2B, and 2C.

As described herein, after a damage ring 325 is created (e.g., at a specified diameter and depth), for example, as described with reference to FIGS. 2A-2C, the damage ring 325 may then be exposed to an etchant. The etchant may include hydrofluoric acid, hydrochloric acid, other acids, or any combination thereof. In some examples, other additives, such as nitric acid, may be used with the etchant to enhance the ability to etch the damage ring 325. In some examples, the substrate 320 may comprise a fused silica material (e.g., a high purity fused silica) and may be etched using one or more etching techniques. The etchant may penetrate the damage ring 325 faster than the surrounding bulk material of the substrate 320 and a pillar contained in the center of the damage ring 325 (e.g., a center pillar 240 as described with reference to FIGS. 2A and 2B). Accordingly, the etchant may increase the diameter of the damage ring 325 in directions 330 both inwards and outwards from the center of the damage ring 325.

The damage ring 325 created by the vortex beam may provide for a preferential etch in the substrate 320, where the etchant may etch a volume associated with the damage ring (e.g., extending from a surface of the substrate 320 to a particular depth of the substrate 320) faster than the surrounding portions of the substrate. As such, the etchant may only affect the damage ring 325 and minimize affecting a center pillar within the vortex damage.

As illustrated, an etchant applied to the substrate 320 and damage ring 325 may affect trench growth in directions 330 radially inward and outward with respect to a center of the damage ring 325. As an example, the substrate 320 including the vortex damage ring 325 may be exposed to etchant for a duration (e.g., 10 minutes), and a trench for an annular via may be formed, where the trench may be grown in both inward and outward directions 330 from the damage ring 325. In other cases, the substrate 320 and damage ring 325 may be exposed to the etchant for longer durations (e.g., 20 minutes), thereby resulting in relatively increased trench growth in the substrate 320. As described herein, an annular width of an annular via may be independent of a diameter of the via, a size of the corresponding damage ring 325, or both. For example, for two damage rings 325 having different diameters and created under the same conditions (e.g., using a vortex beam), as well as having an etchant applied under the same conditions (e.g., same length of time, same type of etchant, and so forth), the resulting annular vias may have relatively similar annular widths. Put another way, the described techniques may provide for multiple annular vias having some constant annular width, regardless of the diameter of the annular shape. In addition, different vias or different substrates, or both, may be etched differently, which may affect a diameter of the center pillar of the annular via, thereby allowing for increased flexibility in via design and configuration.

FIG. 4 illustrates an example of an apparatus 400 including multiple annular vias that supports techniques for creating blind annular vias for metallized vias in accordance with examples as disclosed herein. For example, the apparatus may include a substrate 420 that includes two or more annular vias 425 (e.g., annular via 425-a, annular via 425-b, annular via 425-c) created using a vortex beam followed by etching, as described herein. The substrate 420 may be an example of the substrates 120, 220, 320 described with reference to FIGS. 1 through 3.

In some cases, the annular vias 425-a, 425-b, and 425-c may be created using different orders of a vortex beam or different vortex beams having different orders, resulting in damage rings having radii corresponding to the respective order. As an example, a first annular via 425-a may have a first diameter (e.g., d₁), a second annular via 425-b may have a second diameter (e.g., d₂) greater than the first diameter, and a third annular via 425-c may have a third diameter (e.g., d₃) that is different than the first diameter and the second diameter. It is noted that an order of a vortex beam (or multiple vortex beams) used to create the annular vias 425 may correspond to a center-to-center measurement of the annular via 425, which may define an annulus diameter (e.g., d₁, d₂, d₃) and may, in part, be associated with a diameter of the corresponding pillars. In some cases, an annular width (e.g., w) of an annular via 425 may be based on the etching process or processes used to create the annular via 425. Likewise, a diameter of a pillar of an annular via 425 may be based on the etching process or processes. The damage rings (and corresponding annular vias 425-a, 425-b, and 425-c) created by the vortex beams and subsequent etching may be performed under the same or different conditions, and each of the annular vias 425 may have a trench thicknesses or annular width (e.g., w₁) that is the same, even with varying vortex damage ring diameters. In some examples, the annular width, w₁, may be less than 12 µm. For instance, there may be a relationship between a probability for crack formation in substrates and a conformal conductor ring thickness. In such cases, crack-free TGV substrates may be achieved when the thickness of a metallized annular via 425 is less than 12 µm.

Put another way, various vortex beams may be used to create a variety of annular vias having different radii in the same substrate 420. In such cases, no matter the size of the vortex damage from the vortex beam, an annular trench formed following etching (e.g., as described with reference to FIG. 3) may have the same width and depth under the same etching and time conditions.

Such techniques may allow for any sized annular via 425 created to have a same trench width (e.g., w₁). Such properties may be advantageous when compared to relatively large non-annular vias that may be more difficult to metallize (e.g., due to large gaps left in such vias). As such, annular vias 425 (e.g., even those are relatively large) may be easier to fully fill and create hermeticity. Moreover, the ability of the vortex beam to create etched annular ring sizes of less than 12 µm independent of the via diameter (e.g., d₁, d₂, and d₃), may allow for the formation of reliable metallized TGVs at any diameter that may be free of thermo-mechanically driven cracks, for example, after high temperatures (e.g., up to 420° C., as one example) are applied to the substrate 420 including the annular vias 425. Thus, the described techniques may enable the creation of metallized vias of a same ring thickness but having different outer via diameters on a same wafer or panel.

FIGS. 5A, 5B, 5C, 5D, 5E, and 5F illustrate examples of a method for metallizing a blind annular via that supports techniques for creating blind annular vias for metallized vias in accordance with examples as disclosed herein. Each of FIGS. 5A-5F illustrate a perspective view of a cut-away portion (e.g., a cross-sectional view) of a larger apparatus, for example, including a substrate 520 having a formed annular via 525. The annular via 525 may have an annular shape (e.g., as described with reference to FIGS. 1, 2A-2C, 3, and 4) and may include a pillar 527 that comprises a same material as the substrate 520. The cut-away portion in each figure has been limited to illustrate how various aspects of a metallized annular via may be formed, but additional structure and functionality supporting the annular via (e.g., a TGV) are contemplated. In particular, the described method illustrates aspects of a process for annular via metallization and achievement of a conductive through via.

FIG. 5A illustrates an example of a first operation of a method for metallizing a blind annular via that supports techniques for creating blind annular vias for metallized vias in accordance with examples as disclosed herein. The first operation may not be the first step in the manufacturing process for the annular vias, but it is the first operation described in FIGS. 5A-5F for ease of illustration. FIG. 5A illustrates an apparatus 501 including a substrate 520 (e.g., an optically transmissive substrate) having an annular via 525. The apparatus 501 is an apparatus as it occurs after the first operation in the manufacturing process is complete. For instance, the first operation may include forming at least one blind annular via 525 in the substrate 520 (e.g., by one or more vortex beam damage steps and one or more etching steps). The substrate 520 may be an example of the substrates 120, 220, 320, and 420 described with reference to FIGS. 1 through 4. In some cases, the substrate 520 may comprise glass or fused silica, among other examples.

FIG. 5B illustrates an example of a second operation of a method for metallizing a blind annular via that supports techniques for creating blind annular vias for metallized vias in accordance with examples as disclosed herein. The second operation occurs after the first operation described with reference to FIG. 5A. In some cases, other steps or operations may occur between the first operation and the second operation. FIG. 5B illustrates an apparatus 502 that includes the substrate 520 and the blind annular via 525. The apparatus 502 is an apparatus as it occurs after the second operation in the manufacturing process is complete.

In the second operation, an adhesion layer 530 is deposited on or applied in contact with the substrate 520 within the blind annular via 525. For instance, after the formation of the one or more annular vias 525 using the vortex beam and etching, the adhesion layer 530 (e.g., Ti, TiN, Ta, TaN, TiW, Mo, NiCr, a metal oxide adhesion material, or the like) may be deposited on the annular via 525 (e.g., an annular hole). In some examples, the adhesion layer 530 may promote or enhance the adhesion of one or more additional layers (e.g., of conductive material) on the substrate 520.

FIG. 5C illustrates an example of a third operation of a method for metallizing a blind annular via that supports techniques for creating blind annular vias for metallized vias in accordance with examples as disclosed herein. The third operation occurs after the second operation described with reference to FIG. 5B. In some cases, other steps or operations may occur between the second operation and the third operation. FIG. 5C illustrates an apparatus 503 that includes the substrate 520 and the blind annular via 525 having the adhesion layer 530. The apparatus 503 is an apparatus as it occurs after the third operation in the manufacturing process is complete.

In the third operation, a seed layer 535 (e.g., a copper seed layer) may be deposited in contact with the adhesion layer 530. In some examples, the seed layer 535 may be deposited using sputtering, electroplating, electroless plating, or other techniques. The seed layer 535 may include a conductive material and may serve to promote processes for filling the blind annular via 525 (e.g., as described below with reference to FIG. 5D).

FIG. 5D illustrates an example of a fourth operation of a method for metallizing a blind annular via that supports techniques for creating blind annular vias for metallized vias in accordance with examples as disclosed herein. The fourth operation occurs after the third operation described with reference to FIG. 5C. In some cases, other steps or operations may occur between the third operation and the fourth operation. FIG. 5D illustrates an apparatus 504 that includes the substrate 520 and the blind annular via 525 having the adhesion layer 530 and the seed layer 535 in contact with the adhesion layer 530. The apparatus 504 is an apparatus as it occurs after the fourth operation in the manufacturing process is complete.

As illustrated, the trench corresponding to the blind annular via may be filled (e.g., fully filled) with a conductive material 540 (e.g., Cu). The conductive material 540 may be applied by electroless techniques, electroplating techniques, or other techniques. The application of the conductive material 540 based on the other operations described may thus form a metallized annular via 545. In some examples, fully filling the annular shape of the metallized annular via 545 may provide for the hermetic properties of the metallized annular via 545 (e.g., after polishing). For example, annular vias may be fully filled more efficiently (e.g., excluding via pockets or other defects) as compared to other types of vias or other via shapes.

FIG. 5E illustrates an example of a fifth operation of a method for metallizing a blind annular via that supports techniques for creating blind annular vias for metallized vias in accordance with examples as disclosed herein. The fifth operation occurs after the fourth operation described with reference to FIG. 5D. In some cases, other steps or operations may occur between the fourth operation and the fifth operation. FIG. 5E illustrates an apparatus 505 that includes the substrate 520 and the metallized annular via 545. The apparatus 505 is an apparatus as it occurs after the fifth operation in the manufacturing process is complete.

As shown, an overburden of the adhesion layer 530, the seed layer 535, and the conductive material 540 may be removed from a surface of the substrate 520. For example, the overburden may be removed by chemical-mechanical polishing (CMP). In some examples, the removal of the conductive material 540 may planarize a surface of the substrate and prepare the metallized annular via 545 for additional processing.

FIG. 5F illustrates an example of a sixth operation of a method for metallizing a blind annular via that supports techniques for creating blind annular vias for metallized vias in accordance with examples as disclosed herein. The sixth operation occurs after the fifth operation described with reference to FIG. 5E. In some cases, other steps or operations may occur between the fifth operation and the sixth operation. FIG. 5F illustrates an apparatus 506 that includes the substrate 520 and the metallized annular via 545. The apparatus 506 is an apparatus as it occurs after the sixth operation in the manufacturing process is complete.

As illustrated, a portion 550 of the substrate 520 may be removed for creating a metallized through-substrate annular via 545 (e.g., an He hermetic metallized annular via that is a metallized through-substrate via) having the annular shape. For instance, the portion 550 may be removed by backside grinding, among other examples, thereby enabling the achievement of one or more metallized through vias. In addition, one or more surfaces of the substrate, the metallized through-substrate annular via 545, or both, may be polished (e.g., after the portion 550 is removed). The polishing may result in a hermetic (e.g., He hermetic) metallized annular via 545, and the He hermetic metallized annular via 545 may have an He leak rate of less than or equal to 1 × 10⁻⁵ atm-cc/s. Accordingly, the use of the vortex beam for making blind vias facilitates the use of improved semiconductor metallization schemes and the creation of improved metallized through-substrate vias 545.

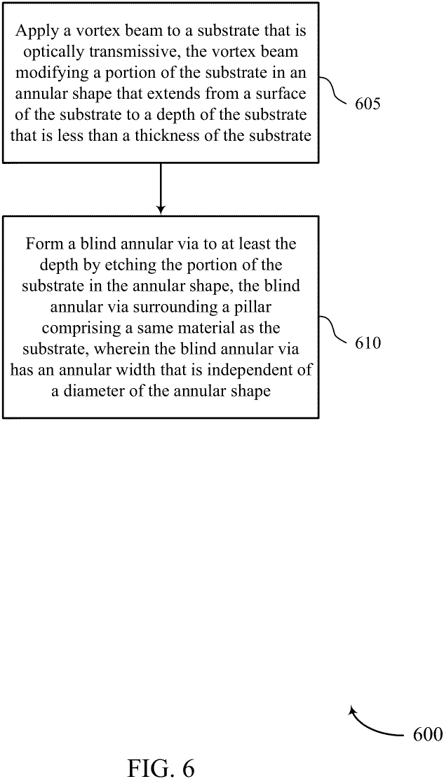

FIG. 6 shows a flowchart illustrating a method 600 that supports techniques for creating blind annular vias for metallized vias in accordance with examples as disclosed herein. The operations of method 600 may be implemented by a system or one or more devices associated with a system. In some examples, one or more controllers may execute a set of instructions to control one or more functional elements of the system to perform the described functions. Additionally or alternatively, one or more controllers may perform aspects of the described functions using special-purpose hardware.

At 605, the method 600 may include applying a vortex beam to a substrate that is optically transmissive, the vortex beam modifying a portion of the substrate in an annular shape that extends from a surface of the substrate to a depth of the substrate that is less than a thickness of the substrate. The operations of 605 may be performed according to the methods described herein. In some cases, the operations of 605 may be performed by a device, such as described with reference to FIG. 1.

At 610, the method 600 may include forming a blind annular via to at least the depth by etching the portion of the substrate in the annular shape, the blind annular via surrounding a pillar including a same material as the substrate, where the blind annular via has an annular width that is independent of a diameter of the annular shape. The operations of 610 may be performed according to the methods described herein. In some cases, the operations of 610 may be performed by a device, such as described with reference to FIG. 1.

In some examples, an apparatus as described herein may perform a method or methods, such as the method 600. The apparatus may include features, means, or instructions (e.g., a non-transitory computer-readable medium storing instructions executable by a processor) for applying a vortex beam to a substrate that is optically transmissive, the vortex beam modifying a portion of the substrate in an annular shape that extends from a surface of the substrate to a depth of the substrate that is less than a thickness of the substrate. Some examples of the method 600 and the apparatus described herein may further include operations, features, means, or instructions for forming a blind annular via to at least the depth by etching the portion of the substrate in the annular shape, the blind annular via surrounding a pillar including a same material as the substrate, where the blind annular via has an annular width that is independent of a diameter of the annular shape.

Some examples of the method 600 and the apparatus described herein may further include operations, features, means, or instructions for applying a second vortex beam to the substrate, the vortex beam modifying a second portion of the substrate in a second annular shape that extends from the surface of the substrate to a second depth of the substrate that is less than the thickness of the substrate, where a second diameter of the second annular shape is different than the diameter of the annular shape.

Some examples of the method 600 and the apparatus described herein may further include operations, features, means, or instructions for forming a second blind annular via to at least the second depth by etching the second portion of the substrate in the second annular shape, the second blind annular via surrounding a second pillar including the same material as the substrate, where the second bind annular via may have a second annular width that is the same as the annular width and may be independent of the second diameter of the second annular shape.

In some examples of the method 600 and the apparatus described herein, the operations, features, means, or instructions for applying the vortex beam to the substrate may further include operations, features, means, or instructions for forming a damage track corresponding to the portion of the substrate that extends from the surface of the substrate to the depth of the substrate, the damage track corresponding to a focal region of the vortex beam within the portion of the substrate, wherein the annular shape has an annular width that is independent of the diameter of the annular shape based on applying the vortex beam.

In some examples of the method 600 and the apparatus described herein, the operations, features, means, or instructions for applying the vortex beam to the substrate may further include operations, features, means, or instructions for applying a single pulse of the vortex beam to form the damage track, where the vortex beam is formed by an illumination source.

Some examples of the method 600 and the apparatus described herein may further include operations, features, means, or instructions for depositing an adhesion layer in contact with the blind annular via formed by etching the portion of the substrate, depositing a seed layer in contact with the adhesion layer, and filling the blind annular via with a conductive material in contact with the seed layer. Some examples of the method 600 and the apparatus described herein may further include operations, features, means, or instructions for forming a metallized annular via by removing a portion of the conductive material, the seed layer, the adhesion layer, or any combination thereof, where the portion of the substrate modified by applying the vortex beam to the substrate does not include a second portion of the substrate at a center of the metallized annular via.

Some examples of the method 600 and the apparatus described herein may further include operations, features, means, or instructions for polishing the metallized annular via after removing at least the portion of the conductive material, where the polished metallized annular via may be helium hermetic having a leak rate of less than or equal to 1 × 10⁻⁵ atm-cc/sec.

In some examples of the method 600 and the apparatus described herein, a ring thickness of the metallized annular via is less than 12 µm, where the substrate including the metallized annular via may exclude cracks after an annealing process having temperatures up to 420° C. is applied to the substrate.

In some examples of the method 600 and the apparatus described herein, the operations, features, means, or instructions for forming the blind annular via by etching may further include operations, features, means, or instructions for etching, while the pillar is in contact with the substrate, the portion of the substrate radially inward and radially outward with respect to the annular shape.

Some examples of the method 600 and the apparatus described herein may further include operations, features, means, or instructions for configuring an order of the vortex beam, where applying the vortex beam to the substrate may be based on configuring the order of the vortex beam, and where the diameter of the annular shape may be based on the order of the vortex beam.

Some examples of the method 600 and the apparatus described herein may further include operations, features, means, or instructions for configuring a focal region of the vortex beam, where the depth of the portion of the substrate may be based on the focal region of the vortex beam.

Some examples of the method 600 and the apparatus described herein may further include operations, features, means, or instructions for configuring the vortex beam at a wavelength that is transparent to the substrate, where a region of the vortex beam that is different than a focal region of the vortex beam passes through the substrate based on the wavelength.

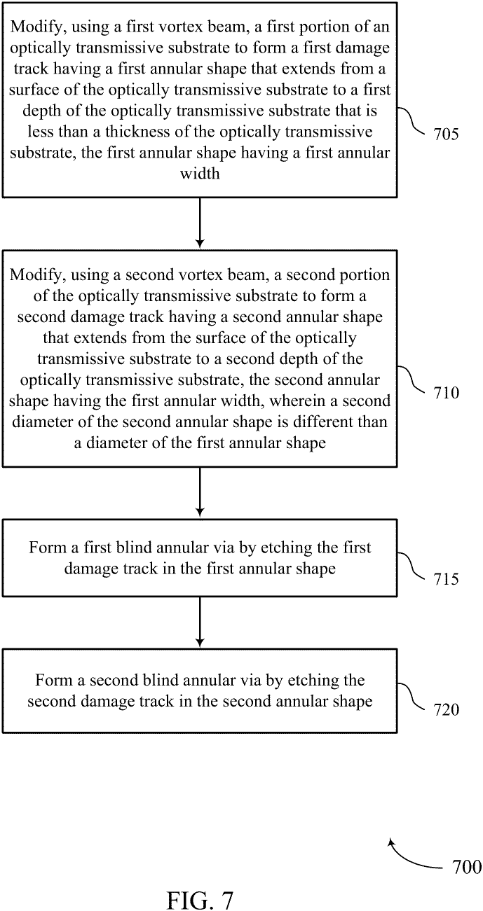

FIG. 7 shows a flowchart illustrating a method 700 that supports techniques for creating blind annular vias for metallized vias in accordance with examples as disclosed herein. The operations of method 700 may be implemented by a system or one or more devices associated with a system. In some examples, one or more controllers may execute a set of instructions to control one or more functional elements of the system to perform the described functions. Additionally or alternatively, one or more controllers may perform aspects of the described functions using special-purpose hardware.

At 705, the method 700 may include modifying, using a first vortex beam, a first portion of an optically transmissive substrate to form a first damage track having a first annular shape that extends from a surface of the optically transmissive substrate to a first depth of the optically transmissive substrate that is less than a thickness of the optically transmissive substrate, the first annular shape having a first annular width. The operations of 705 may be performed according to the methods described herein. In some cases, the operations of 705 may be performed by a device, such as described with reference to FIG. 1.

At 710, the method 700 may include modifying, using a second vortex beam, a second portion of the optically transmissive substrate to form a second damage track having a second annular shape that extends from the surface of the optically transmissive substrate to a second depth of the optically transmissive substrate, the second annular shape having the first annular width, where a second diameter of the second annular shape is different than a diameter of the first annular shape. The operations of 710 may be performed according to the methods described herein. In some cases, the operations of 710 may be performed by a device, such as described with reference to FIG. 1.

At 715, the method 700 may include forming a first blind annular via by etching the first damage track in the first annular shape. The operations of 715 may be performed according to the methods described herein. In some cases, the operations of 715 may be performed by a device, such as described with reference to FIG. 1.

At 720, the method 700 may include forming a second blind annular via by etching the second damage track in the second annular shape. The operations of 720 may be performed according to the methods described herein. In some cases, the operations of 720 may be performed by a device, such as described with reference to FIG. 1.

In some examples, an apparatus as described herein may perform a method or methods, such as the method 700. The apparatus may include features, means, or instructions (e.g., a non-transitory computer-readable medium storing instructions executable by a processor) for modifying, using a first vortex beam, a first portion of an optically transmissive substrate to form a first damage track having a first annular shape that extends from a surface of the optically transmissive substrate to a first depth of the optically transmissive substrate that is less than a thickness of the optically transmissive substrate, the first annular shape having a first annular width. Some examples of the method 700 and the apparatus described herein may further include operations, features, means, or instructions for modifying, using a second vortex beam, a second portion of the optically transmissive substrate to form a second damage track having a second annular shape that extends from the surface of the optically transmissive substrate to a second depth of the optically transmissive substrate, the second annular shape having the first annular width, where a second diameter of the second annular shape is different than a diameter of the first annular shape.

Some examples of the method 700 and the apparatus described herein may further include operations, features, means, or instructions for forming a first blind annular via by etching the first damage track in the first annular shape and forming a second blind annular via by etching the second damage track in the second annular shape.

Some examples of the method 700 and the apparatus described herein may further include operations, features, means, or instructions for depositing an adhesion layer in contact with at least one of the first blind annular via or the second blind annular via, depositing a seed layer in contact with the adhesion layer, and forming, from at least one of the first blind annular via or the second blind annular via, a metallized blind annular via by filling at least one of the first blind annular via or the second blind annular via with a conductive material in contact with the seed layer. Some examples of the method 700 and the apparatus described herein may further include operations, features, means, or instructions for forming at least one metallized annular through-substrate via by modifying a third portion of the optically transmissive substrate that is opposite the surface of the optically transmissive substrate. Some examples of the method 700 and the apparatus described herein may further include operations, features, means, or instructions for polishing one or more surfaces of the at least one metallized annular through-substrate via, the at least one polished metallized annular through-substrate via being He hermetic and having a leak rate of less than or equal to 1 × 10⁻⁵ standard atmosphere-cubic centimeters per second, where a ring thickness of the at least one metallized annular through-substrate via is less than 12 µm, and where the optically transmissive substrate excludes cracks after the optically transmissive substrate including the at least one metallized annular through-substrate via undergoes a heating process having temperatures up to 420° C.

Some examples of the method 700 and the apparatus described herein may further include operations, features, means, or instructions for modifying an order of the first vortex beam from a first order to a second order different than the first order, where the second diameter of the second annular shape corresponds to the second order of the second vortex beam.

In some examples of the method 700 and the apparatus described herein, the first blind annular via may surround a first pillar including the optically transmissive substrate, the first pillar having a third diameter, and the second blind annular via may surround a second pillar including the optically transmissive substrate, the second pillar having a fourth diameter different than the third diameter of the first pillar.

It should be noted that the methods described herein describe possible implementations, and that the operations and the functions may be rearranged or otherwise modified and that other implementations are possible. Further, aspects of two or more of the described methods may be combined.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The various illustrative blocks, components, and modules described in connection with the disclosure herein may be implemented or performed with a general-purpose processor. A general-purpose processor may be a microprocessor, but in the alternative, the processor may be any processor, controller, microcontroller, or state machine. A processor may also be implemented as a combination of computing devices.

The functions described herein may be implemented in hardware, software executed by a processor, firmware, or any combination thereof. Features implementing functions may also be physically located at various positions, including being distributed such that portions of functions are implemented at different physical locations. Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary function that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person having ordinary skill in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
applying a vortex beam to a substrate that is optically transmissive, the vortex beam modifying a portion of the substrate in an annular shape that extends from a surface of the substrate to a depth of the substrate that is less than a thickness of the substrate; and
forming a blind annular via to at least the depth by etching the portion of the substrate in the annular shape, the blind annular via surrounding a pillar comprising a same material as the substrate, wherein the blind annular via has an annular width that is independent of a diameter of the annular shape.

2. The method of claim 1, further comprising:
applying a second vortex beam to the substrate, the vortex beam modifying a second portion of the substrate in a second annular shape that extends from the surface of the substrate to a second depth of the substrate that is less than the thickness of the substrate, wherein a second diameter of the second annular shape is different than the diameter of the annular shape; and
forming a second blind annular via to at least the second depth by etching the second portion of the substrate in the second annular shape, the second blind annular via surrounding a second pillar comprising the same material as the substrate, wherein the second bind annular via has a second annular width that is the same as the annular width and is independent of the second diameter of the second annular shape.

3. The method of claim 1, wherein applying the vortex beam to the substrate comprises:
forming a damage track corresponding to the portion of the substrate that extends from the surface of the substrate to the depth of the substrate, the damage track corresponding to a focal region of the vortex beam within the portion of the substrate, wherein the annular shape has an annular width that is independent of the diameter of the annular shape based at least in part on applying the vortex beam.

4. The method of claim 3, wherein applying the vortex beam to the substrate comprises:
applying a single pulse of the vortex beam to form the damage track, wherein the vortex beam is formed by an illumination source.

5. The method of claim 1, further comprising:
depositing an adhesion layer in contact with the blind annular via formed by etching the portion of the substrate;
depositing a seed layer in contact with the adhesion layer;
filling the blind annular via with a conductive material in contact with the seed layer; and
forming a metallized annular via by removing a portion of the conductive material, the seed layer, the adhesion layer, or any combination thereof, wherein the portion of the substrate modified by applying the vortex beam to the substrate does not include a second portion of the substrate at a center of the metallized annular via.

6. The method of claim 5, further comprising:
polishing the metallized annular via after removing at least the portion of the conductive material, wherein the polished metallized annular via is helium hermetic having a leak rate of less than or equal to 1 × 10⁻⁵ standard atmosphere-cubic centimeters per second.

7. The method of claim 5, wherein a ring thickness of the metallized annular via is less than 12 micrometers, and wherein the substrate comprising the metallized annular via excludes cracks after an annealing process having temperatures up to 420° C. is applied to the substrate.

8. The method of claim 1, wherein forming the blind annular via by etching comprises:
etching, while the pillar is in contact with the substrate, the portion of the substrate radially inward and radially outward with respect to the annular shape.

9. The method of claim 1, further comprising:
configuring an order of the vortex beam, wherein applying the vortex beam to the substrate is based at least in part on configuring the order of the vortex beam, and wherein the diameter of the annular shape is based at least in part on the order of the vortex beam.

10. The method of claim 1, further comprising:
configuring a focal region of the vortex beam, wherein the depth of the portion of the substrate is based at least in part on the focal region of the vortex beam.

11. The method of claim 1, further comprising:
configuring the vortex beam at a wavelength that is transparent to the substrate, wherein a region of the vortex beam that is different than a focal region of the vortex beam passes through the substrate based at least in part on the wavelength.

12. An apparatus, comprising:
a substrate that is optically transmissive and comprises one or more annular vias formed by a vortex beam in an annular shape that is etched, the annular shape having an annular width that is a same size for one or more diameters of the annular shape, wherein the one or more annular vias extend from a surface of the substrate to a depth of the substrate and each of the one or more annular vias surround a pillar comprising a same material as the substrate.

13. The apparatus of claim 12, wherein the one or more annular vias comprise a first annular via having a first diameter and a second annular via having a second diameter greater than the first diameter, the first annular via and the second annular via having the annular width.

14. The apparatus of claim 12, wherein:
the annular width is less than or equal to 12 micrometers;
each annular via of the one or more annular vias comprises a metallized annular via including conducting material surrounding the pillar, wherein the substrate excludes cracks after temperatures of up to 420° C. are applied to the substrate; and
the substrate comprises a glass material.

15. The apparatus of claim 14, wherein the metallized annular via is helium hermetic having a helium leak rate less than or equal to 1 × 10⁻⁵ standard atmosphere-cubic centimeters per second, and wherein a center portion of the pillar includes substrate material that is not modified by the vortex beam.

16. The apparatus of claim 12, wherein the annular shape comprises a non-scalloped profile based at least in part on the vortex beam.

17. A method, comprising:
modifying, using a first vortex beam, a first portion of an optically transmissive substrate to form a first damage track having a first annular shape that extends from a surface of the optically transmissive substrate to a first depth of the optically transmissive substrate that is less than a thickness of the optically transmissive substrate, the first annular shape having a first annular width;
modifying, using a second vortex beam, a second portion of the optically transmissive substrate to form a second damage track having a second annular shape that extends from the surface of the optically transmissive substrate to a second depth of the optically transmissive substrate, the second annular shape having the first annular width, wherein a second diameter of the second annular shape is different than a diameter of the first annular shape;
forming a first blind annular via by etching the first damage track in the first annular shape; and
forming a second blind annular via by etching the second damage track in the second annular shape.

18. The method of claim 17, further comprising:
forming, from at least one of the first blind annular via or the second blind annular via, a metallized blind annular via by filling at least one of the first blind annular via or the second blind annular via with a conductive material;
forming at least one metallized annular through-substrate via by modifying a third portion of the optically transmissive substrate that is opposite the surface of the optically transmissive substrate; and
polishing one or more surfaces of the at least one metallized annular through-substrate via, the at least one polished metallized annular through-substrate via being helium hermetic and having a leak rate of less than or equal to 1 × 10⁻⁵ standard atmosphere-cubic centimeters per second, wherein a ring thickness of the at least one metallized annular through-substrate via is less than 12 micrometers, and wherein the optically transmissive substrate excludes cracks after the optically transmissive substrate comprising the at least one metallized annular through-substrate via undergoes a heating process having temperatures up to 420° C.

19. The method of claim 17, further comprising:
modifying an order of the first vortex beam from a first order to a second order different than the first order, wherein the second diameter of the second annular shape corresponds to the second order of the second vortex beam.

20. The method of claim 17, wherein the first blind annular via surrounds a first pillar comprising the optically transmissive substrate, the first pillar having a third diameter, and wherein the second blind annular via surrounds a second pillar comprising the optically transmissive substrate, the second pillar having a fourth diameter different than the third diameter of the first pillar.
